(19) United States
(12) Patent Application Publication
(10) Pub. No.: US 2006/0160345 A1
(43) Pub. Date: Jul. 20, 2006

(54) Innovative growth method to achieve high quality III-nitride layers for wide band gap optoelectronic and electronic devices

(76) Inventors: Xing-Quan Liu, Brea, CA (US); Huoping Xin, Brea, CA (US); Jin Joo Song, Brea, CA (US); Thomas K. Choo, Brea, CA (US)

Correspondence Address: THE ECLIPSE GROUP, 10605 BALBOA BLVD., SUITE 300, GRANADA HILLS, CA, 91344, US

(21) Appl. No.: 11/036,081

(22) Filed: Jan. 14, 2005

(51) Int. Cl. H01L 29/22; H01L 21/28; H01L 31/0296

(52) U.S. Cl. 438/604; 257/78

(57) ABSTRACT

A method to achieve high quality III-nitride epitaxial layers including AlN, AlGaN, GaN, InGaN, and AlInGaN, by supplying group III precursors constantly and group V precursors periodically with the epitaxial growth systems including metal organic chemical vapor deposition (MOCVD), hydride vapor phase epitaxy (HVPE), and molecular beam epitaxy (MBE).

### BACKGROUND OF THE INVENTION

1. Field of Invention

The invention relates to a method of making high quality electronic and optoelectronic device structures, and more particularly to III-nitride electronic and optoelectronic devices.

2. Related Art

There is a growing worldwide demand for ultraviolet (UV) light emitting diodes (LEDs). The UV LEDs are typically used in such applications as biochemical media detection, white light sources, and UV detection to name but a few. High quality UV LEDs may be manufactured using wide band gap III-nitride material approaches such as AlₓGa₁₋ₓN on GaN, AlN, SiC substrates. Some known approaches also have used sapphire substrates with mixed results.

Some of the approaches that are known in the art use AlₓGa₁₋ₓN on sapphire substrates, such as AlN/AlₓGa₁₋ₓN superlattice and high temperature AlN (HT-AlN) on sapphire substrates. The HT-AlN layer acts as a buffer and strain-releasing layer. However, a problem exists that the quality of AlₓGa₁₋ₓN epitaxial layer grown on the HT-AlN template is limited by the quality of the HT-AlN buffer layer. Even the quality of the AlN/AlₓGa₁₋ₓN superlattice is limited by the quality of the AlN layers.

In a conventional Epitaxy approach, a common approach for HT-AlN growth is commonly referred to as continuous epitaxy, during which both the Group III source flow and the Group V source flow (ammonia) are supplied simultaneously and continuously. This approach is a very efficient way, particularly for the mass production. In FIG. 1 a precursor flow chart 100 of the conventional epitaxy approach is shown. A TMAL flow 102 and NH₃ flow 104 are continuous supplied simultaneously. However, this continuous epitaxy approach results in HT-AlN epitaxial layers that have a rougher surface than when other known approaches are used. In FIG. 2(a), the atomic force microscope (AFM) image illustrates a 0.3 μm thick HT-AlN layer with root mean square (RMS) roughness around 11 nm.

In another approach, commonly called a pulsed atomic layer epitaxy (PALE) approach, improved HT-AlN epitaxial layer quality on sapphire substrates was achieved. PALE was realized by alternatively supplying the Group III precursors and Group V precursors to prevent their pre-reaction and enhance the Group III elements mobility on the substrate surface to achieve atomic layer epitaxy. In FIG. 3 a typical precursor flow chart of the PALE approach is shown with the TMAL flow 302 alternating with the NH₃ flow 304. However, the PALE approach has too low a growth rate for mass production, and too frequent valve actions that shorten the hardware lifetime and lead to inconsistent materials quality.

Yet another approach is the “initially alternating supply of ammonia” (IASA) approach that utilizes direct epitaxy on the sapphire substrate without low-temperature (LT) AlN nuclei layer, and was claimed to achieve atomic scale flatness by just alternatively supplying ammonia at an initial stage directly on sapphire substrates. However, this approach suffers from a number of disadvantages. First of all, the IASA approach requires direct epitaxy on the sapphire surface without an LT-AlN nuclei layer. Thus, the advantage of LT-AlN acting as a strain management layer is absent in the IASA approach. Secondly, IASA approach is very sensitive to the state of surface cleanness or the gas atmospheric state to achieve the step-flow growth mode. Therefore, good reproducibility is difficult to achieve. The third disadvantage of IASA is it has an unknown growth mechanism, for example the inversion of the sample polarity compared to the conventional epitaxy.

Therefore, there is a need in the art for a system and method to produce devices that overcome the drawbacks and issues in the known approaches discussed above.

### SUMMARY

The present invention relates to III-nitride electronic and optoelectronic devices, and methods of making high quality device structures, which are based on AlN, GaN, InGaN, AlGaN or AlInGaN single crystal epitaxial layers.

A breathing mode epitaxy (BME) approach achieves ultrahigh quality III-nitride epitaxial layers on a low temperature nuclei layer, by supplying the Group V precursors periodically, while keeping the Group III precursor flow constant. In a BME growth mode, AlN epitaxial layers with atomic scale flattened surface have been achieved and the pre-reaction of the precursors was not an issue in the cold wall reactors. The BME approach is an epitaxy technique on a low temperature grown nuclei layer; the reproducibility is very high due to the strain management function of this low temperature grown nuclei layer. Meanwhile the growth rate is kept similar to conventional epitaxy, which is suitable for mass production. The BME technique may also extend machine lifetime in mass production due to much less frequent valve actions than the PALE method.

Other systems, methods, features and advantages of the invention will be or will become apparent to one with skill in the art upon examination of the following figures and detailed description. It is intended that all such additional systems, methods, features and advantages be included within this description, be within the scope of the invention, and be protected by the accompanying claims.

### BRIEF DESCRIPTION OF THE DRAWINGS

The invention can be better understood with reference to the following figures. The components in the figures are not necessarily to scale, emphasis instead being placed upon illustrating the principles of the invention. In the figures, like reference numerals designate corresponding parts throughout the different views.

FIG. 1 shows a prior art precursor flow chart of a conventional epitaxy approach.

FIG. 2 shows a prior art atomic force microscope (AFM) image illustrates a 0.3 μm thick HT-AlN layer with root mean square (RMS) roughness around 11 nm.

FIG. 3 is a typical prior art precursor flow chart of the pulsed atomic layer epitaxy (PALE) approach.

FIG. 4 is a precursor flow chart of the BME growth in accordance with an implementation of the invention.

FIG. 5 shows the time-dependent reflectivity spectra of different continuous epitaxy growth and BME growth runs.

FIG. 6 shows AFM images of the HT-AlN epilayers grown with the BME approach.

FIG. 7 shows the X-ray rocking curves of HT-AlN epitaxial layers grown with the continuous approach and BME approach, respectively.

FIG. 8 shows the forward bias I-V curves for UV LED manufactured with the continuous approach and BME approach, respectively.

FIG. 9 is the flow diagram of a BME mode process implementation.

### DETAILED DESCRIPTION

In the following description of the preferred implementation, reference is made to the accompanying drawings that form a part hereof, and in which is shown by way of illustration a specific implementation in which the invention may be practiced. It is to be understood that other implementations may be utilized and structural changes may be made without departing from the scope of the present invention.

The present implementation has an epitaxy of atomic scale flattened HT-AlN epitaxial layer on a LT-AlN nuclei layer. Compared with those based on conventional grown HT-AlN buffer layers, high quality AlₓGa₁₋ₓN epitaxial layers and much improved UV light emitters (UVLEDs) based on BME-grown HT-AlN on sapphire have been demonstrated.

In FIG. 4, a precursor flow chart of the BME growth in accordance with an implementation is shown. An LT-AlN nuclei layer (20˜100 nm) is grown on sapphire substrate at a low temperature range (500˜650 C.) by continuous growth. After the growth of the LT-AlN nuclei layer, the temperature is raised to the high temperature range for HT-AlN growth. The high temperature range for BME growth is typically between 1,000˜1,200 C. During the BME growth, trimethyl aluminum (TMAL) 402 as the Group III precursor is continuously supplied, while ammonia as the Group V precursor 404 is supplied periodically. The time period for ammonia may be selected to obtain the smoothest surface with time range between 0.1˜1,200 seconds.

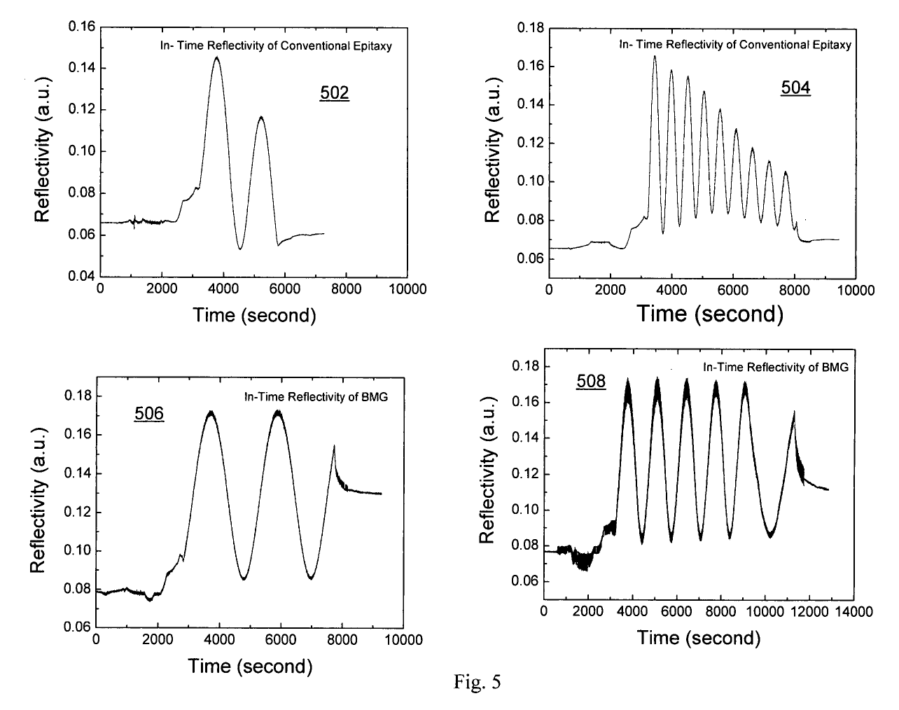

Turning to FIG. 5, the time-dependent reflectivity spectra of different continuous epitaxy growth and BME growth runs are shown. The epitaxy growth was monitored by in-situ reflectivity spectroscopy. The different graphs of FIG. 5 (502, 504, 506, and 508) show the time-dependent reflectivity spectra of different growth runs, where spectra 502 & 504 are of continuous epitaxy growth runs, and spectra 506 & 508 are of BME growth runs. A short run and a long run are shown for each of the two types of epitaxy. The time-dependent reflectivity oscillations are clearly seen in these spectra, caused by the variation of epitaxial film thickness. The magnitude of the oscillation keeps dropping for the continuous growth of HT-AlN, indicating the worsening surface roughness during the growth. This shows that a three dimensional (3-D) growth is the major growth mode in the continuous growth of HT-AlN. In contrast, the reflectivity spectra of both short and long runs of the BME mode growth are shown to be a constant oscillation of the reflectivity. Thus, the surface roughness was maintained during the growth, indicating a two-dimensional (2-D) growth mode dominates the BME growth.

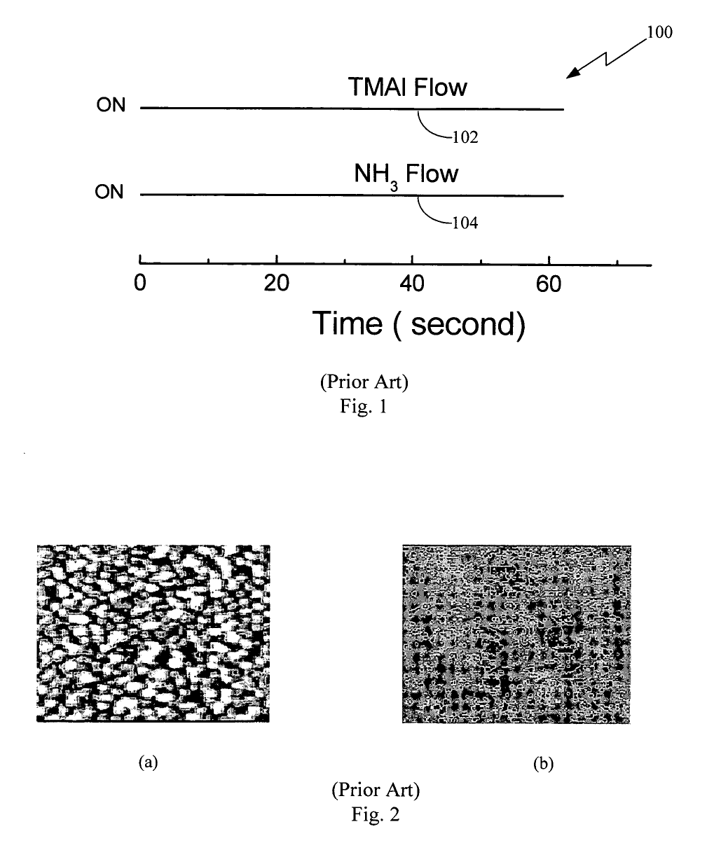

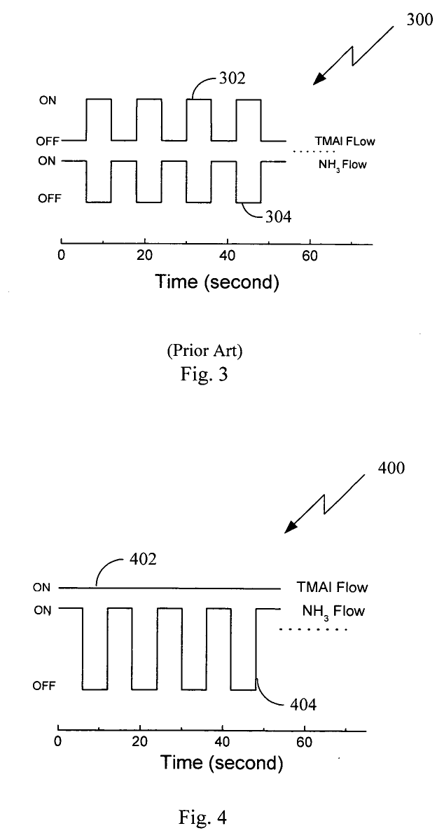

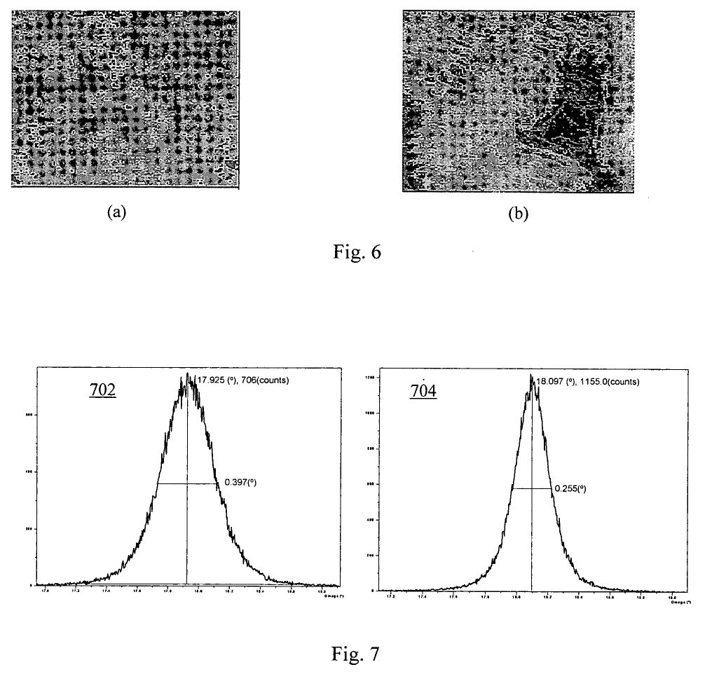

In FIG. 6, the AFM images of the HT-AlN epilayers grown with the BME mode are shown. The layer thickness of both types (BME and continuous modes, shown in FIG. 6(a) and FIG. 2(a), respectively) of HT-AlN layers was approximately 0.3 μm. The difference of the surface morphology of these two types of HT-AlN layers can be seen clearly. The root mean square (RMS) roughness of the continuous growth layer of FIG. 2(a) was 11 nm, while for the BME mode grown HT-AlN layer of FIG. 6(a) was only 0.14 nm, approximately two orders of magnitude smaller. In addition, the AFM images of AlₓGa₁₋ₓN epitaxial layers grown on top of these two HT-AlN buffer layers are also shown in FIG. 2(b) and FIG. 6(b), respectively. Significant differences in surface morphology are observable between these two AlₓGa₁₋ₓN layers. Although both layers show similar RMS roughness around 0.3 nm, the one on top of continuous mode HT-AlN (FIG. 2(b)) has high density of pits, which are the cross points of threading dislocation with sample surface. The atomic layer step bunches in FIG. 2(b) are also not clear. The AlₓGa₁₋ₓN layer on top of BME HT-AlN (FIG. 6(b)), however, shows a much smaller density of pits, and much more clear step bunch, indicating that the step-flow 2D growth mode dominates the whole AlₓGa₁₋ₓN epitaxy process.

The threading dislocation is often an issue in manufactured devices. A high density of threading dislocations result in lines of crystal defects that start at the substrate and propagate vertically up to the surface and adversely affect the performance of the manufactured device or may even cause premature failure of the manufactured device. It is desirable to have a low threading dislocation density. The lower the threading dislocation density, the better the manufactured device will perform.

X-ray rocking curves are measured to further characterize the epitaxial layer quality. Turning to FIG. 7, an X-ray rocking curves of HT-AlN epitaxial layers grown with continuous mode 702 and BME mode 704, respectively is shown. The full width at half maximum (FWHM) of the rocking curve of the 0.3 μm thick HT-AlN epitaxial layer grown with continuous mode is 24 arc minutes, but is only 16 arc minutes for the HT-AlN layer grown with BME mode. The X-ray rocking curves of 2 μm thick AlₓGa₁₋ₓN epitaxial layers grown on top of these two HT-AlN buffer layers also show significant differences: the FWHM is 12 arc minutes for AlₓGa₁₋ₓN on continuous mode HT-AlN and is only 7.6 arc minutes for AlₓGa₁₋ₓN on BME mode HT-AlN. Thus, the BME approach is shown to be superior to the typical continuous approach.

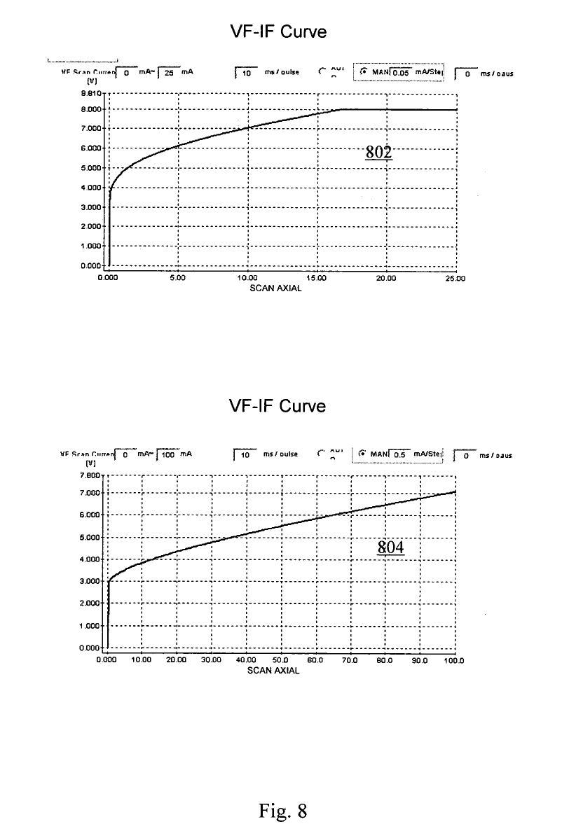

By using this BME approach, the quality of the HT-AlN and AlₓGa₁₋ₓN epitaxial layers has been significantly improved, including better surface roughness and smaller threading dislocation density. The performance of any device based on AlₓGa₁₋ₓN is improved by using BME mode grown HT-AlN buffer layer. In a comparison study, 340 nm UVLED structures (simplest conventional UV LED p-on-n structures) were deposited on HT-AlN buffer layers grown with continuous mode and BME mode epitaxy, respectively. The UV LED structures were then processed with a standard 350×350 μm² device mesa geometry. Significant performance differences between these two UV LEDs were observed in both the I-V characteristics and light output power (LOP). In FIG. 8, the forward bias I-V curves for continuously grown HT-AlN 802 and BME grown HT-AlN 804 are shown. One visible difference is that the turn-on voltage of the UV LED based on BME-grown HT-AlN is ˜0.5 V lower than that based on the continuous mode grown HT-AlN. At a forward bias value of 7 V, the current is about 100 mA flowing through the UV LED based on BME-grown HT-AlN, but only 10 mA for the one based on continuous mode HT-AlN. The root cause of this difference is that the quality of the conductive layers (both p-type and n-type layers) is improved by using BME HT-AlN buffer layer. The conductivity is improved due to fewer defects, such as threading dislocations. Consequently, higher current was allowed. In these UV LEDs, the LOP is also improved by over 75% by using BME-grown HT-AlN buffer layer instead of the continuous mode grown HT-AlN buffer. The better crystal quality has resulted in higher emission efficiency, which is desirable in light emitting application.

Thus, the BME approach achieves high quality III-nitride epitaxial layers by supplying group III precursors constantly and group V precursors periodically. This approach may be used for different kinds of III-nitride materials growth, including AlN, AlGaN, GaN, InGaN, and AlInGaN, and also their intentiously doped counterparts by using Group VI elements such as Si and Group II elements such as Mg. The growth temperature for the BME approach may be in the range of 600-1,200 degrees Celsius with a flow rate of Group III precursors in the range of 1˜5,000 sccm. The flow rate of the Group V precursors may be in the range of 1˜30,000 sccm during a pulse width lasting from 0.1˜600 seconds with a period of flow separation between pulses of 0.1-600 seconds. The number of repetition of the Group V precursor may be 1˜10,000 times. Further, the number of Group III precursors incorporated into the Group III precursor flow may be 1˜5, while the number of types of Group V precursors incorporated into the Group V precursor flow may be 1˜5. The epitaxial growth systems may include metal organic chemical vapor deposition (MOCVD), hydride vapor phase epitaxy (HVPE), and molecular beam epitaxy (MBE).

The BME approach may start with a substrate of sapphire, SiC, Si, ZnO, AlN, GaN, GaAs, or other oxides and semiconductors. A low temperature nuclei layer of AlN or GaN grown by MOCVD, HVPE, or MBE at temperatures of 300˜700 C. may be deposited on the substrate. Epitaxial structures with one or more III-nitride layers grown with the BME approach by MOCVD, HVPE, or MBE may then be formed. The BME approach may result in devices fabricated from the epitaxial structures, such as optical, electronic, optoelectronic, magnetic, and micro-electronic (including MEMS) devices, including but not limited to the following devices, such as UV LEDs, UV lasers, UV detectors, blue LEDs, blue lasers, field emission transistors (FET), and high mobility transistors (HBT), in which at least one III-nitride layer is fabricated by using BME mode growth or BME mode grown templates, upon which epitaxial layers can be grown, allowing devices to be further fabricated.

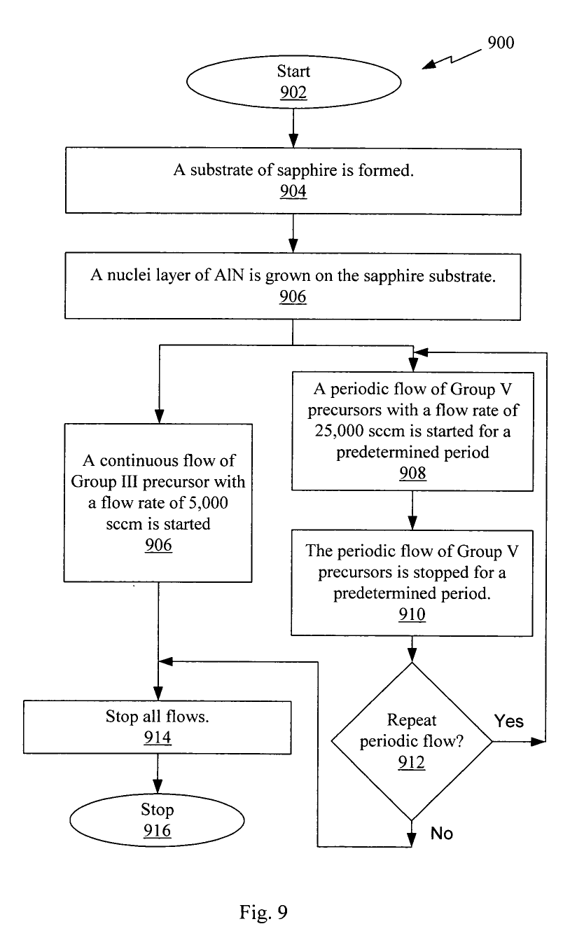

Turning to FIG. 9, a flow diagram 900 of a BME mode process implementation is shown. The diagram starts 902 with a sapphire substrate being formed 904. A nuclei layer of AlN is then grown on the sapphire substrate 906 to act as a buffer and strain-releasing layer. A continuous flow of Group III precursors with a flow rate of 5,000 sccm is started 906 and a periodic flow of Group V precursors with a flow rate of 25,000 sccm is started for a predetermined period 908. The periodic flow of Group V precursors is then stopped for a predetermined period 910. The application of the Group V precursors may be repeated 910 for a predetermined number of iterations while the continuous flow of Group III precursors is occurring. Upon the periodic flow not being repeated 912, all flows stop 914, and the BME processing is complete 916. More epitaxial growth may follow to complete the device structure. The resulting device then has the characteristics as previously described.

While various embodiments of the invention have been described, it will be apparent to those of ordinary skill in the art that many more embodiments and implementations are possible that are within the scope of this invention.

What is claimed is:

1. A method comprising:
forming a nuclei layer on a substrate;
forming epitaxial layers on top of the nuclei layer, at temperatures 600˜1,200 C.; and
applying a Group III precursor to the nuclei layer at a continuous flow rate; and
applying a Group V precursor to the nuclei layer at predetermined periodic periods.

2. The method of claim 1, where forming a nuclei layer further includes:
growing the nuclei layer with metal organic chemical vapor deposition,

3. The method of claim 1, where forming a nuclei layer further includes:
forming the nuclei layer with hydride vapor phase epitaxy.

4. The method of claim 1, where forming a nuclei layer further includes:
forming the nuclei layer with molecular beam epitaxy.

5. The method of claim 1, where applying a Group III precursor at a continuous flow rate, further includes:
applying the Group III precursor at a flow rate selected from 1 to 5,000 sccm.

6. The method of claim 5, where applying a Group V precursor at a predetermined periodic periods, further includes:
applying the Group V precursor at a flow rate selected from 1 to 30,000 sccm.

7. The method of claim 1, where the predetermined periodic periods is selected from 0.1-600 seconds.

8. The method of claim 1, further includes a separation period between the predetermined periodic periods that is selected from 0.1 to 600 seconds.

9. The method of claim 1, further includes:
repeating the predetermined periodic periods for a number of iterations selected from 1 to 10,000 times.

10. The method of claim 1, where the Group III precursor further include:
mixing more than one Group III precursors together.

11. The method of claim 1, where the Group V precursor further includes:
mixing more than one Group V precursors together.

12. The method of claim 1, where the nuclei layer is an AlN layer.

13. The method of claim 1, where the substrate is a sapphire substrate.

14. A semiconductor device, comprising:
a substrate;
a nuclei layer;
an epitaxial structure with at least one III-nitride layer formed by BME that has a continuous Group III precursor and a periodic Group V precursor.

15. The semiconductor device of claim 14, where the substrate is a sapphire.

16. The semiconductor device of claim 14, where the substrate is formed with at least one of the following: SiC, Si, ZnO, MgO, Zn_{1-x-y}MgₓCd_{y}O (where x=0-1, y=0-1), ZnSO, LiAlO₂, LiGaO₂, MgAl₂O₄, AlN, GaN, InN, Al_{1-x-y}InₓGa_{y}N (where x=0-1, y=0-1), InP, or GaAs.

17. The semiconductor device of claim 14, where the nuclei layer is an AlN or GaN layer.

18. The semiconductor device of claim 14, where the semiconductor device is a blue LED.

19. The semiconductor device of claim 14, where the semiconductor device is an ultraviolet LED.

20. A device comprising:
means for forming a nuclei layer on a substrate;
means for applying a Group III precursor to the nuclei layer at a continuous flow rate; and
means for applying a Group V precursor to the nuclei layer at predetermined periodic periods.

21. The device of claim 20, where forming means further includes:
means for growing the nuclei layer with metal organic chemical vapor deposition.

22. The device of claim 20, where forming means further includes:
forming the nuclei layer with hydride vapor phase epitaxy.

23. The device of claim 20, where forming means further includes:
forming the nuclei layer with molecular beam epitaxy.

24. The device of claim 20, where applying means at a continuous flow rate, further includes:
means for applying the Group III precursor at a flow rate selected from 1 to 5,000 sccm.

25. The method of claim 24, where applying means at predetermined periodic periods, further includes:
means for applying the Group V precursor at a flow rate selected from 1 to 30,000 sccm.
